(19) United States
(12) Patent Application Publication
(10) Pub. No.: US 2025/0221098 A1
(43) Pub. Date: Jul. 3, 2025

(54) NITRIDE SEMICONDUCTOR LIGHT-EMITTING ELEMENT

(71) Applicant: NIKKISO CO., LTD., Tokyo (JP)

(72) Inventors: Kazufumi TAKAO, Ishikawa (JP); Yusuke MATSUKURA, Ishikawa (JP); Cyril PERNOT, Ishikawa (JP)

(73) Assignee: NIKKISO CO., LTD., Tokyo (JP)

(21) Appl. No.: 19/002,134

(22) Filed: Dec. 26, 2024

(30) Foreign Application Priority Data
Dec. 27, 2023 (JP) 2023-220368

(51) Int. Cl. H10H 20/815; H10H 20/825

(52) U.S. Cl. CPC H10H 20/815; H10H 20/8252

(57) ABSTRACT

A nitride semiconductor light-emitting element includes a substrate including a growth surface that is a c-plane having an off angle, an AlN buffer layer comprising AlN and being formed on the growth surface, an n-type semiconductor layer formed on the AlN buffer layer, an active layer being formed on the n-type semiconductor layer and emitting ultraviolet light, and a p-type semiconductor layer formed on the active layer. An upper surface of the AlN buffer layer includes a step-and-terrace structure including a plurality of terraces and a plurality of steps connecting between the terraces. An average of heights of the plurality of steps is not more than 7.1 nm. An average of widths of the plurality of terraces is not more than 350 nm.

### CROSS-REFERENCE TO RELATED APPLICATIONS

The present application is based on Japanese patent application No. 2023-220368 filed on Dec. 27, 2023, the entire contents of which are incorporated herein by reference.

### TECHNICAL FIELD

The present invention relates to a nitride semiconductor light-emitting element.

### BACKGROUND OF THE INVENTION

Patent Literature 1 discloses an ultraviolet light-emitting element that includes a substrate, an underlying layer formed on the substrate, a first cladding layer formed on the underlying layer, a light-emitting layer formed on the first cladding layer and emitting ultraviolet light, and a second cladding layer formed on the light-emitting layer. In the ultraviolet light-emitting element described in Patent Literature 1, the step height at an interface between the underlying layer and the first cladding layer is not less than 10 nm and not more than 60 nm.

Citation List Patent Literature 1: JP2019-29607A

### SUMMARY OF THE INVENTION

In Patent Literature 1, however, light output of the ultraviolet light-emitting element in case of having a relatively small step height has not been considered.

The invention was made in view of such circumstances and it is an object of the invention to provide a nitride semiconductor light-emitting element that can achieve improved light output.

To achieve the object described above, the invention provides a nitride semiconductor light-emitting element, comprising:
a substrate comprising a growth surface that is a c-plane having an off angle;
an AlN buffer layer comprising AlN and being formed on the growth surface;
an n-type semiconductor layer formed on the AlN buffer layer;
an active layer being formed on the n-type semiconductor layer and emitting ultraviolet light; and
a p-type semiconductor layer formed on the active layer,
wherein an upper surface of the AlN buffer layer comprises a step-and-terrace structure comprising a plurality of terraces and a plurality of steps connecting between the terraces,
wherein an average of heights of the plurality of steps is not more than 7.1 nm, and
wherein an average of widths of the plurality of terraces is not more than 350 nm.

### ADVANTAGEOUS EFFECTS OF THE INVENTION

According to the invention, it is possible to provide a nitride semiconductor light-emitting element that can achieve improved light output.

### BRIEF DESCRIPTION OF DRAWINGS

FIG. 1 is a schematic diagram illustrating a configuration of a nitride semiconductor light-emitting element in an embodiment.

FIG. 2 is an enlarged schematic cross-sectional view showing a portion of the nitride semiconductor light-emitting element in the embodiment.

FIG. 3A is an AFM image showing an upper surface of an AlN buffer layer of a wafer grown under the same manufacturing conditions as in Example 1.

FIG. 3B is a cross-sectional profile of a position indicated by a dash-dot line in FIG. 3A.

FIG. 4A is an AFM image showing an upper surface of an AlN buffer layer of a wafer grown under the same manufacturing conditions as in Comparative Example 1.

FIG. 4B is a cross-sectional profile of a position indicated by a dash-dot line in FIG. 4A.

FIG. 5 is a graph showing a relationship between average step height and light output in Experimental Example.

FIG. 6 is a graph showing a relationship between average terrace width and light output in Experimental Example.

### DETAILED DESCRIPTION OF THE INVENTION

### Embodiment

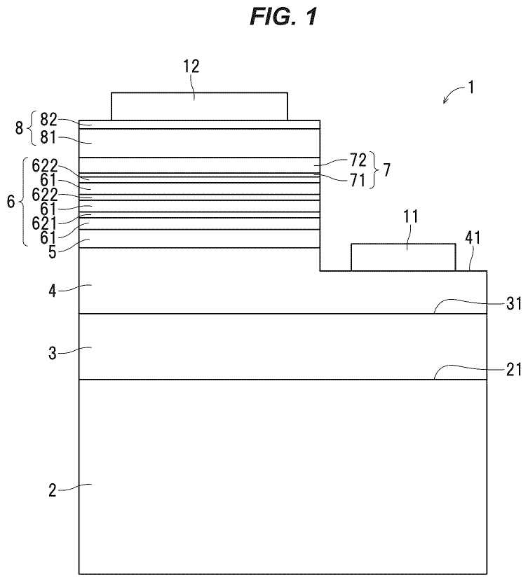

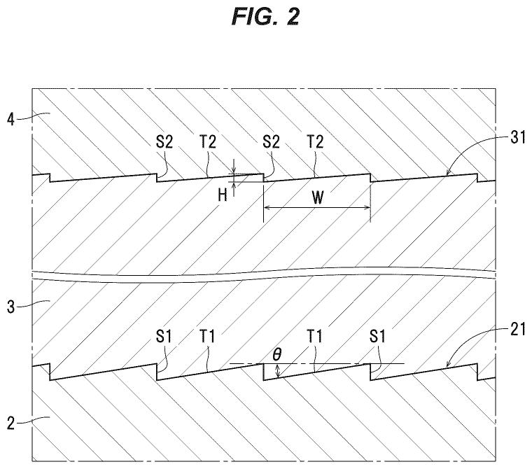

An embodiment of the invention will be described in reference to FIGS. 1 and 2. The embodiment below is described as a preferred illustrative example for implementing the invention. Although some part of the embodiment specifically illustrates various technically preferable matters, the technical scope of the invention is not limited to such specific aspects.

### Nitride Semiconductor Light-Emitting Element 1

FIG. 1 is a schematic diagram illustrating a configuration of a nitride semiconductor light-emitting element 1. In FIG. 1, the scale ratio of each semiconductor layer of the nitride semiconductor light-emitting element 1 (hereinafter, also simply referred to as the “light-emitting element 1”) in a stacking direction is not necessarily the same as the actual scale ratio. Hereinafter, the direction of stacking each semiconductor layer of the light-emitting element 1 (i.e., a direction orthogonal to the bottom surface of a substrate 2) is referred to as the up-and-down direction. In addition, one side in the up-and-down direction, which is a side of a substrate 2 where each semiconductor layer is grown, (e.g., an upper side in FIG. 1) will be referred to as the upper side, and the opposite side (e.g., a lower side in FIG. 1) will be referred to as the lower side. In this regard, the terms “upper” and “lower” are used for descriptive purposes and do not limit the posture of the light-emitting element 1 with respect to the vertical direction when, e.g., the light-emitting element 1 is used.

The light-emitting element 1 constitutes, e.g., a light-emitting diode (LED) or a semiconductor laser (LD: laser diode). In the present embodiment, the light-emitting element 1 constitutes a light-emitting diode that emits light with a wavelength in an ultraviolet region. Particularly, the light-emitting element 1 in the present embodiment emits ultraviolet light at a central wavelength of not less than 240 nm and not more than 365 nm. The light-emitting element 1 can be used in fields such as, e.g., sterilization (e.g., air purification, water purification, etc.), medical treatment (e.g., light therapy, measurement/analysis, etc.), UV curing, etc.

The light-emitting element 1 includes an AlN buffer layer 3, an n-type semiconductor layer 4, a composition gradient layer 5, an active layer 6, an electron blocking layer 7 and a p-type semiconductor layer 8 in this order on the substrate 2. The light-emitting element 1 also includes an n-side electrode 11 provided on the n-type semiconductor layer 4, and a p-side electrode 12 provided on the p-type semiconductor layer 8.

As semiconductors constituting the light-emitting element 1, it is possible to use, e.g., binary to quaternary group III nitride semiconductors expressed by AlₐGa_{b}In_{1-a-b}N (0≤a≤1, 0≤b≤1, 0≤a+b≤1). In the present embodiment, binary or ternary group III nitride semiconductors expressed by Al_{c}Ga_{1-c}N (0≤c≤1) are used as the semiconductors constituting the light-emitting element 1. These group III elements may be partially substituted with boron (B) or thallium (Tl), etc. In addition, nitrogen (N) may be partially substituted with phosphorus (P), arsenic (As), antimony (Sb) or bismuth (Bi), etc.

The substrate 2 is made of a material transparent to light emitted by the active layer 6. The substrate 2 is a sapphire (Al₂O₃) substrate. FIG. 2 is a schematic cross-sectional view parallel to the up-and-down direction of the light-emitting element 1, and is an enlarged schematic cross-sectional view showing the area around the AlN buffer layer 3. A growth surface 21 being an upper surface of the substrate 2 is a c-plane having an off angle θ. The off angle θ is, e.g., not less than 0.2° and not more than 1.5°, and more preferably 1.0°±0.3° (i.e., not less than 0.7° and not more than 1.3°). In this regard, FIG. 2 is merely a schematic diagram, and the shapes of the growth surface 21 of the substrate 2 and an upper surface 31 of the AlN buffer layer 3 may differ from the actual shapes.

The growth surface 21 of the substrate 2 has a step-and-terrace that has plural terraces T1 constituted by a c-plane having an off angle θ, and plural steps S1 connecting between the terraces T1. In the step-and-terrace structure, the terraces T1 and the steps S1 are alternately formed into a multi-step pattern. The substrate 2 is not particularly limited, and may be, e.g., a substrate having an off angle θ of 0.2° and an average terrace width of 60.2 nm, a substrate having an off angle θ of 0.6° and an average terrace width of 20.1 nm, a substrate having an off angle θ of 1.0° and an average terrace width of 12.0 nm, or a substrate having an off angle θ of 1.5° and an average terrace width of 8.0 nm. Alternatively, e.g., an aluminum nitride (AlN) substrate or an aluminum gallium nitride (AlGaN) substrate, etc. may be used as the substrate 2.

The AlN buffer layer 3 is formed on the substrate 2. The AlN buffer layer 3 is made of undoped aluminum nitride. Undoped semiconductor layer means a semiconductor layer to which impurities are not intentionally added during formation of the semiconductor layer, and semiconductor layers containing trace amounts of inevitably included impurities are also regarded as undoped semiconductor layers.

The AlN buffer layer 3 is formed by step-flow growth, and the upper surface 31 of the AlN buffer layer 3 has a step-and-terrace structure having plural terraces T2 inclined with respect to a virtual plane orthogonal to the up-and-down direction and plural steps S2 connecting between the terraces T2.

On the upper surface 31 of the AlN buffer layer 3, an average of heights H of the steps S2 is not more than 7.1 nm and an average of widths of the terraces T2 is not more than 350 nm. It is presumed that this causes the active layer 6, which is formed using the AlN buffer layer 3 as an underlying layer, to be appropriately flattened and improves monochromaticity of light emitted from the active layer 6, resulting in that light output of the light-emitting element 1 in a desired wavelength range is improved. The height H of the step S2 is a length of the step S2 in the up-and-down direction. The width of the terrace T2 is a length of the terrace T2 in a direction which is one of directions orthogonal to up-and-down direction and in which the terraces T2 and the steps S2 are continuous (e.g., the left-right direction in FIG. 2). Hereinafter, the average of the heights H of the steps S2 on the upper surface 31 of the AlN buffer layer 3 will also be referred to as the “average step height”, and the average of the widths W of the terraces T2 on the upper surface 31 of the AlN buffer layer 3 will also be referred to as the “average terrace width”.

The average step height is preferably less than 7.0 nm, and the average terrace width is more preferably not more than 325 nm. In addition, from the viewpoint of causing step-flow growth of the AlN buffer layer 3, it is preferable that the average step height be not less than 5.0 nm and the average terrace width be not less than 250 nm.

The average step height can be calculated, for example, as follows: First, the surface profile of the AlN buffer layer 3 is measured using an atomic force microscope (AFM). Then, at least one cross-sectional profile along both the up-and-down direction and the direction in which the terraces T2 and steps S2 are continuous is extracted from the measured AFM image. Then, the average of the heights H of the steps S2 is obtained by dividing the sum of the heights H of the plural steps S2 appeared in the at least one extracted cross-sectional profile by the number of steps S2.

Likewise, the average terrace width is obtained, e.g., by dividing the sum of the widths of the terraces T2 appeared in the at least one extracted cross-sectional profile by the number of terraces T2, as described above.

A buffer layer made of undoped AlₚGa₁₋ₚN (0≤p≤1) may be additionally included on the AlN buffer layer 3.

The n-type semiconductor layer 4 is formed on the AlN buffer layer 3. The n-type semiconductor layer 4 is, e.g., an n-type cladding layer made of Al_{q}Ga_{1-q}N (0≤q≤1) doped with an n-type impurity. In the present embodiment, silicon (Si) is used as the n-type impurity. The same applies to the semiconductor layers containing an n-type impurity other than the n-type semiconductor layer 4. Alternatively, germanium (Ge), selenium (Se) or tellurium (Te), etc. may be used as the n-type impurity. The Al composition ratio q of the n-type semiconductor layer 4 is, e.g., not less than 45% and not more than 65%.

The shape of the upper surface of the n-type semiconductor layer 4 is transferred from the shape of the upper surface 31 of the AlN buffer layer 3. At this time, it is considered that the shape of the upper surface of the n-type semiconductor layer 4 becomes flatter with increasing the film thickness of the n-type semiconductor layer 4 up to a certain film thickness, but once the film thickness of the n-type semiconductor layer 4 becomes more than the certain film thickness, there is substantially no change in the shape of the upper surface of the n-type semiconductor layer 4 associated with an increase in film thickness. The n-type semiconductor layer 4 is a semiconductor layer passing electric current and is thus formed to have a relatively large film thickness (e.g., not less than 1 μm) to allows the passage the electric current, and the film thickness usually adopted for the n-type semiconductor layer 4 is larger than the above-mentioned certain film thickness. In the present embodiment, the film thickness of the n-type semiconductor layer 4 is, e.g., not less than 1600 nm and not more than 3600 nm. The n-type semiconductor layer 4 may have a single-layer structure or may have a multilayer structure.

The composition gradient layer 5 is formed on the n-type semiconductor layer 4. The composition gradient layer 5 is made of AlᵣGa₁₋ᵣN (0≤r≤1). In the composition gradient layer 5, an Al composition ratio in the up-and-down direction is higher at an upper position. The composition gradient layer 5 may have, e.g., a very small region in the up-and-down direction (e.g., a region of not more than 5% of the entire composition gradient layer 5 in the up-and-down direction) in which the Al composition ratio does not increase toward the upper side.

The Al composition ratio of a lower end portion of the composition gradient layer 5 is preferably substantially the same (e.g., a difference within 5%) as an Al composition ratio of an upper portion of the n-type semiconductor layer 4 that is adjacent to the composition gradient layer 5 on the lower side. In addition, the Al composition ratio of an upper end portion of the composition gradient layer 5 is preferably substantially the same (e.g., a difference within 5%) as an Al composition ratio of a lower portion of a barrier layer 61 that is adjacent to the composition gradient layer 5 on the upper side. The composition gradient layer 5 is doped with silicon. The silicon concentration in the composition gradient layer 5 is, e.g., not less than 5.0×10¹⁸ atoms/cm³ and not more than 5.0×10¹⁹ atoms/cm³.

The active layer 6 is formed on the composition gradient layer 5. The active layer 6 in the present embodiment has a multiple quantum well structure which includes plural well layers 621, 622. A band gap of the active layer 6 is adjusted so that ultraviolet light at a central wavelength of not less than 240 nm and not more than 365 nm can be output. When the active layer 6 has a multiple quantum well structure as in the present embodiment, the central wavelength of ultraviolet light emitted by the active layer 6 is preferably not less than 250 nm and not more than 300 nm, more preferably, not less than 260 nm and not more than 290 nm from the viewpoint of improving light output. In the present embodiment, the active layer 6 has three barrier layers 61 and three well layers 621, 622 which are alternately stacked. In the active layer 6, the barrier layer 61 is located at the lower end and the well layer 622 is located at the upper end.

Each barrier layer 61 is made of AlₛGa₁₋ₛN (0<s≤1). An Al composition ratio s of each barrier layer 61 is, e.g., not less than 75% and not more than 95%. Each barrier layer 61 has a film thickness of, e.g., not less than 2 nm and not more than 50 nm.

The well layers 621, 622 are made of AlₜGa₁₋ₜN (0<t<1). An Al composition ratio t of each of the well layers 621, 622 is smaller than the Al composition ratio s of the barrier layers 61 (i.e., t<s).

The three well layers 621, 622 are configured such that the lowermost well layer 621, which is the well layer arranged on the lowermost side, has a different configuration from the upper-side well layers 622 which are two well layers other than the lowermost well layer 621. For example, a film thickness of the lowermost well layer 621 is not less than 1 nm greater than a film thickness of each of the two upper-side well layers 622 and the Al composition ratio of the lowermost well layer 621 is not less than 2% greater than the Al composition ratio of each of the two upper-side well layers 622. In the present embodiment, the upper-side well layers 622 have a film thickness of not less than 2 nm and not more than 4 nm and an Al composition ratio of not less than 25% and not more than 45%, and the lowermost well layer 621 has a film thickness of not less than 4 nm and not more than 6 nm and an Al composition ratio of not less than 35% and not more than 55%. A difference between the film thickness of the lowermost well layer 621 and the film thickness of each upper-side well layer 622 can be not less than 2 nm and not more than 4 nm.

By increasing the Al composition ratio of the lowermost well layer 621 to higher than the Al composition ratio of the upper-side well layers 622, crystallinity of the lowermost well layer 621 is improved. This is because the difference in the Al composition ratio between the lowermost well layer 621 and the n-type semiconductor layer 4 is reduced. The improved crystallinity of the lowermost well layer 621 improves crystallinity of each semiconductor layer formed on and above the lowermost well layer 621 in the active layer 6. As a result, carrier mobility in the active layer 6 is improved and light output is improved. Such effects are more pronounced when the lowermost well layer 621 has a larger film thickness, but the film thickness of the lowermost well layer 621 is designed to be not more than a predetermined value from the viewpoint of suppressing an increase in the electrical resistance value of the entire light-emitting element 1.

Although the example in which the active layer 6 has a multiple quantum well structure with the three well layers 621, 622 has been described in the present embodiment, it is not limited thereto. The active layer 6 may have a multiple quantum well structure with two or not less than four well layers. Alternatively, the active layer 6 may have a single quantum well structure having only one well layer.

The electron blocking layer 7 is formed on the active layer 6. The electron blocking layer 7 serves to improve efficiency of electron injection into the active layer 6 by suppressing occurrence of the overflow phenomenon in which electrons leak from the active layer 6 to the p-type semiconductor layer 8 side (hereinafter, also referred to as the electron blocking effect). The electron blocking layer 7 has a stacked structure in which a first layer 71 and a second layer 72 are stacked in this order from the lower side.

The first layer 71 is provided on the active layer 6. The first layer 71 is made of, e.g., AlᵤGa₁₋ᵤN (0<u≤1). An Al composition ratio u of the first layer 71 is, e.g., not less than 90% and is made of aluminum nitride in the present embodiment. A film thickness of the first layer 71 is, e.g., not less than 0.5 nm and not more than 5.0 nm.

The second layer 72 is made of, e.g., AlᵥGa₁₋ᵥN (0<v<1). An Al composition ratio v of the second layer 72 is smaller than the Al composition ratio t of the first layer 71 (i.e., v<t) and is, e.g., not less than 70% and not more than 90%. A film thickness of the second layer 72 is larger than the film thickness of the first layer 71 and is, e.g., not less than 15 nm and not more than 100 nm.

When the first layer 71 with a relatively high Al composition ratio has an excessively large film thickness, it causes an excessive increase in the electrical resistance value of the entire light-emitting element 1 since a semiconductor layer with a higher Al composition ratio has a higher electrical resistance value. For this reason, the film thickness of the first layer 71 is preferably small to some extent. On the other hand, if the film thickness of the first layer 71 is reduced, it increases the probability that electrons pass through the first layer 71 from the lower side to the upper side due to the tunnel effect. Therefore, in the light-emitting element 1 of the present embodiment, the second layer 72 is formed on the first layer 71 to suppress passage of electrons through the entire electron blocking layer 7.

Each of the first layer 71 and the second layer 72 can be an undoped layer, a layer containing an n-type impurity, a layer containing a p-type impurity, or a layer containing both an n-type impurity and a p-type impurity. Magnesium (Mg) can be used as the p-type impurity, but zinc (Zn), beryllium (Be), calcium (Ca), strontium (Sr), barium (Ba) or carbon (C), etc. may be used other than magnesium. The same applies to the other semiconductor layers containing a p-type impurity. When each electron blocking layer 7 contains an impurity, the impurity in each electron blocking layer 7 may be contained in the entire portion of each electron blocking layer 7 or may be contained in a part of each electron blocking layer 7. In the present embodiment, the entire electron blocking layer 7 is an undoped layer.

The p-type semiconductor layer 8 is formed on the electron blocking layer 7. The p-type semiconductor layer 8 has a lower Al composition ratio than that of the electron blocking layer 7 and is made of Al_{w}Ga_{1-w}N (0≤w≤1) doped with a p-type impurity. In the present embodiment, the p-type semiconductor layer 8 has a p-type cladding layer 81 and a p-type contact layer 82 in this order from the lower side.

The p-type cladding layer 81 is provided so as to be in contact with an upper surface of the electron blocking layer 7. An Al composition ratio of the p-type cladding layer 81 can be set to lower than an Al composition ratio of a semiconductor layer of the electron blocking layer 7 adjacent to the p-type cladding layer 81 (i.e., lower than the Al composition ratio of the second layer 72), and higher than an Al composition ratio of the p-type contact layer 82. A film thickness of the p-type cladding layer 81 is, e.g., not less than 9 nm and not more than 105 nm.

The p-type contact layer 82 is a layer connected to the p-side electrode 12 (described later) and is doped with a high concentration of a p-type impurity. The p-type contact layer 82 is configured to have a low Al composition ratio (e.g., not more than 10%) to achieve an ohmic contact with the p-side electrode 12, and from such a viewpoint, the p-type contact layer 82 is preferably made of p-type gallium nitride (GaN). Since the p-type contact layer 82 with a low Al composition ratio can absorb ultraviolet light emitted from the active layer 6, a film thickness of the p-type contact layer 82 is preferably not more than 50 nm, more preferably, not more than 25 nm. The film thickness of the p-type contact layer 82 is also preferably not less than 5 nm from the viewpoint of suppressing occurrence of short circuit.

The n-side electrode 11 is formed on an exposed surface 41 of the n-type semiconductor layer 4 which is exposed from the active layer 6 on the upper side. The n-side electrode 11 can be, e.g., a multilayered film formed by sequentially stacking titanium (Ti), aluminum, titanium and titanium nitride (TiN) on the n-type semiconductor layer 4. When the light-emitting element 1 is flip-chip mounted as described below, the n-side electrode 11 may be composed of a material that can reflect ultraviolet light emitted by the active layer 6.

The p-side electrode 12 is formed on an upper surface of the p-type semiconductor layer 8. The p-side electrode 12 can be made of, e.g., rhodium (Rh). In the present embodiment, the p-side electrode 12 is, but not limited to, a reflective electrode that has a reflectance of not less than 50%, preferably not less than 60%, at the central wavelength of light emitted by the active later 6.

The light-emitting element 1 can be used in a state of being flip-chip mounted on a package substrate (not shown). That is, the light-emitting element 1 is mounted such that a side in the up-and-down direction, which is a side where the n-side electrode 11 and the p-side electrode 12 are provided, faces the package substrate and each of the n-side electrode 11 and the p-side electrode 12 is attached to the package substrate via a gold bump, etc. Light from the flip-chip mounted light-emitting element 1 is extracted on the substrate 2 side (i.e., on the lower side). However, it is not limited thereto and the light-emitting element 1 may be mounted on the package substrate by wire bonding, etc. In addition, although the light-emitting element 1 in the present embodiment is a so-called lateral light-emitting element in which both the n-side electrode 11 and the p-side electrode 12 are provided on the upper side of the light-emitting element 1, the light-emitting element 1 is not limited thereto and may be a vertical light-emitting element. The vertical light-emitting element is a light-emitting element in which the active layer is sandwiched between the n-side electrode and the p-side electrode.

### Method for Manufacturing Light-Emitting Element 1

Next, an example of a method for manufacturing the light-emitting element 1 in the present embodiment will be described.

In the present embodiment, the AlN buffer layer 3, the n-type semiconductor layer 4, the composition gradient layer 5, the active layer 6, the electron blocking layer 7 and the p-type semiconductor layer 8 are epitaxially grown on the disc-shaped substrate 2 in this order by the Metal Organic Chemical Vapor Deposition (MOCVD) method. That is, in the present embodiment, the disc-shaped substrate 2 is placed in a chamber and each semiconductor layer is formed on the substrate 2 by introducing source gases of each semiconductor layer to be formed on the substrate 2 into the chamber. As the source gases to epitaxially grow each semiconductor layer, it is possible to use trimethylaluminum (TMA) as an aluminum source, trimethylgallium (TMG) as a gallium source, ammonia (NH₃) as a nitrogen source, tetramethylsilane (TMSi) as a silicon source, and biscyclopentadienylmagnesium (Cp₂Mg) as a magnesium source.

The MOCVD method is sometimes called the Metal Organic Vapor Phase Epitaxy (MOVPE) method. To epitaxially grow each semiconductor layer on the substrate 2, it is also possible to use another epitaxial growth method such as the Molecular Beam Epitaxy (MBE) method or the Hydride Vapor Phase Epitaxy (HVPE) method, etc.

In the method for manufacturing the light-emitting element 1 in the present embodiment, the manufacturing conditions are designed so as to have the average step height of not more than 7.1 nm and the average terrace width of not more than 350 nm on the upper surface 31 of the AlN buffer layer 3. For example, there is a tendency that the average step height is lower when the growth rate of the AlN buffer layer 3 is higher. Adjustment of the growth rate of the AlN buffer layer 3 can be achieved, e.g., by adjusting the growth temperature or source gas supply amount, etc. for the AlN buffer layer 3. The appropriate value for each manufacturing condition may vary depending on other manufacturing conditions and may also vary depending on the manufacturing equipment used. In addition, the shape of the upper surface 31 of the AlN buffer layer 3 is affected not only by the growth rate but also by the shape of the growth surface 21 of the substrate 2. By appropriately adjusting the factors that affect the upper surface 31 of the AlN buffer layer 3 as described above, the AlN buffer layer 3 is formed by step-flow growth and the upper surface 31 thereof is formed in the shape described above.

After forming each semiconductor layer on the disc-shaped substrate 2, a mask is formed on a portion of the p-type semiconductor layer 8, i.e., a part other than the portion to be the exposed surface 41 of the n-type semiconductor layer 4. Then, the region in which the mask is not formed is removed by etching from the upper surface of the p-type semiconductor layer 8 to the middle of the n-type semiconductor layer 4 in the up-and-down direction. The exposed surface 41 exposed upward is thereby formed on the n-type semiconductor layer 4. After forming the exposed surface 41, the mask is removed.

Subsequently, the n-side electrode 11 is formed on the exposed surface 41 of the n-type semiconductor layer 4 and the p-side electrode 12 is formed on the p-type semiconductor layer 8. The n-side electrode 11 and the p-side electrode 12 may be formed by, e.g., a well-known method such as the electron beam evaporation method or the sputtering method. The object completed through the above process is cut into pieces with a desired dimension. Plural light-emitting elements 1 as shown in FIG. 1 are thereby obtained from one wafer.

### Functions and Effects of the Embodiment

In the light-emitting element 1 of the present embodiment, the upper surface 31 of the AlN buffer layer 3 has a step-and-terrace structure that has the plural terraces T2 and the plural steps S2 connecting between the terraces T2. Then, on the upper surface 31 of the AlN buffer layer 3, the average step height is not more than 7.1 nm and the average terrace width is not more than 350 nm. Therefore, it is possible to improve the light output of the light-emitting element 1. It is presumed that this causes the active layer 6, which is formed using the AlN buffer layer 3 as an underlying layer, to be appropriately flattened and improves monochromaticity of light emitted from the active layer 6, resulting in that the light output of the light-emitting element 1 in a desired wavelength range is improved. These numerical values are supported by Experimental Example described later.

Furthermore, the average step height is less than 7.0 nm. Therefore, it is possible to further improve the light output of the light-emitting element 1. This numerical value is supported by Experimental Example described later.

Furthermore, the average terrace width is not more than 325 nm. Therefore, it is possible to further improve light output of the light-emitting element 1. This numerical value is supported by Experimental Example described later.

In addition, the light emitting device 1 further includes the composition gradient layer 5 that is located between the n-type semiconductor layer 4 and the active layer 6 and has an Al composition ratio increasing toward the active layer 6. This improves the crystallinity of the active layer 6. Therefore, configuring to have the average step height of not more than 7.1 nm and the average terrace width of not more than 350 nm, together with the flattening of the active layer 6, facilitates further improvement in the light output.

In addition, in the light-emitting element 1, the p-side electrode 12 is composed of a reflective electrode and the film thickness of the p-type contact layer 82 is not more 50 nm. In other words, the light-emitting element 1 in the present embodiment has a configuration in which ultraviolet light emitted from the active layer 6 toward the p-side electrode 12 is reflected at the p-side electrode 12 and is extracted from the substrate 2 side. In case of having such a configuration, a phase difference between directly-exiting light, which is emitted from the active layer 6 directly toward the substrate 2, and reflected light, which is emitted from the active layer 6, reflected at the p-side electrode 12 and extracted from the substrate 2 side, is designed so that the directly-exiting light and the reflected light interfere to amplify each other. However, when flatness of each interface between semiconductor layers is poor, light scattering is likely to occur at each interface between semiconductor layers, resulting in that the directly-exiting light and the reflected light are unlikely to be in phase and this may impair improvement in the light output. On the other hand, since the light-emitting element 1 in the present embodiment has the average step height of not more than 7.1 nm and the average terrace width of not more than 350 nm on the upper surface 31 of the AlN buffer layer 3 as described above, it is considered that each semiconductor layer deposited on the AlN buffer layer 3 also has a small step height and a small terrace width (i.e., improved flatness) in the similar manner. Therefore, in the light-emitting element 1 of the present embodiment, occurrence of light scattering at each interface between the semiconductor layers is suppressed and the directly-exiting light and the reflected light are likely to be in phase, resulting in that the light output is improved easily.

As described above, according to the present embodiment, it is possible to provide a nitride semiconductor light-emitting element that can achieve improved light output.

### Experiment Example

This Experimental Example is an example of evaluating light output of wafer when the average step height and the average terrace width on the upper surface of the AlN buffer layer are changed to different values. Among constituent elements in this Experimental Example, the constituent elements denoted by the same names as those in the already-described embodiment indicate the same constituent elements as those in the already-described embodiment, unless otherwise specified

In this Experimental Example, wafers in Examples 1 to 5 and Comparative Examples 1 to 3 were prepared. As shown in Table 1 below, the wafers in Examples 1 to 5 and Comparative Examples 1 to 3 have the same basic structure as the light-emitting element in the embodiment. The differences between Examples 1 to 5 and Comparative Examples 1 to 3, which will be described in detail later, are the average step height and the average terrace width. Table 1 shows the basic configuration common to the wafers in Examples 1 to 5 and Comparative Examples 1 to 3.

TABLE 1

| | | | Al composition |
|---|---|---|---|
| Structure | | Film thickness | ratio [%] |
| Substrate | | 430 ± 25 [um] | — |
| Buffer layer | | 2000 ± 200 [nm] | 100 |
| n-type semiconductor layer | | 2000 ± 200 [nm] | 55 ± 10 |
| Composition gradient layer | | 15 ± 5 [nm] | 55→85 |
| Active layer | Barrier layer | 7 ± 5 [nm] | 85 ± 10 |
| (3QW) | Well layer | 5 ± 1 [nm] | 45 ± 10 |
| | (Lowermost | | |
| | well layer) | | |
| | Barrier layer | 7 ± 5 [nm] | 85 ± 10 |
| | Well layer | 3 ± 1 [nm] | 35 ± 10 |
| | (Upper-side | | |
| | well layer) | | |
| | Barrier layer | 7 ± 5 [nm] | 85 ± 10 |
| | Well layer | 3 ± 1 [nm] | 35 ± 10 |
| | (Upper-side | | |
| | well layer) | | |
| Electron | First layer | 2 ± 1.5 [nm] | 95 ± 5 |
| blocking layer | Second layer | 20 ± 10 [nm] | 80 ± 10 |
| P-type | p-type | 30 ± 20 [nm] | 60 ± 5 |
| semiconductor | cladding layer | | |
| layer | p-type | 22 ± 20 [nm] | 0 |
| | contact layer | | |

The Al composition ratio of each layer shown in Table 1 is a value estimated from secondary ion intensity of Al measured by secondary ion mass spectrometry (SIMS). In addition, the figure in the column of Al composition ratio for Composition gradient layer in Table 1 indicates that the Al composition ratio of the composition gradient layer in the up-and-down direction gradually increases from 55% to 85% from the lower end to the upper end of the composition gradient layer. For the wafers in Examples 1 to 5 and Comparative Examples 1 to 3, the substrate having the growth surface which is a c-plane having an off angle of 1.0°±0.3° was used.

Then, the average step height and the average terrace width were calculated for the wafers in Examples 1 to 5 and Comparative Examples 1 to 3. The methods for calculating these will be described below.

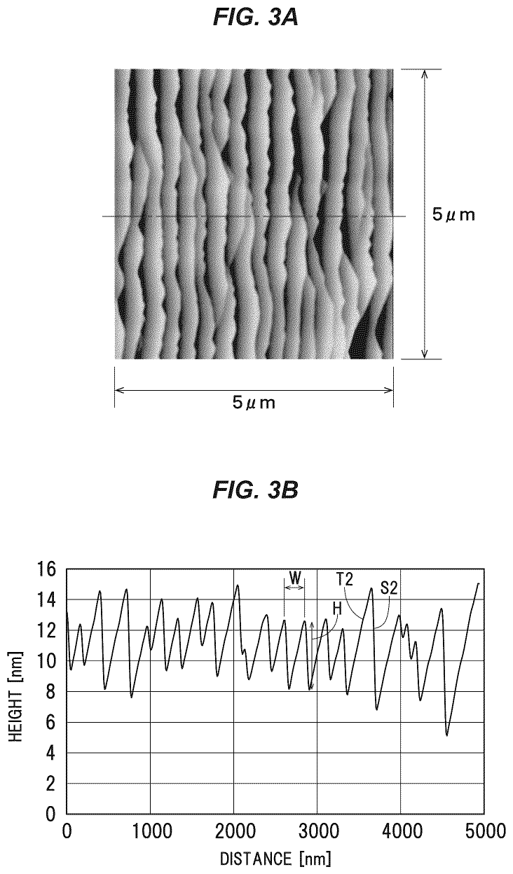

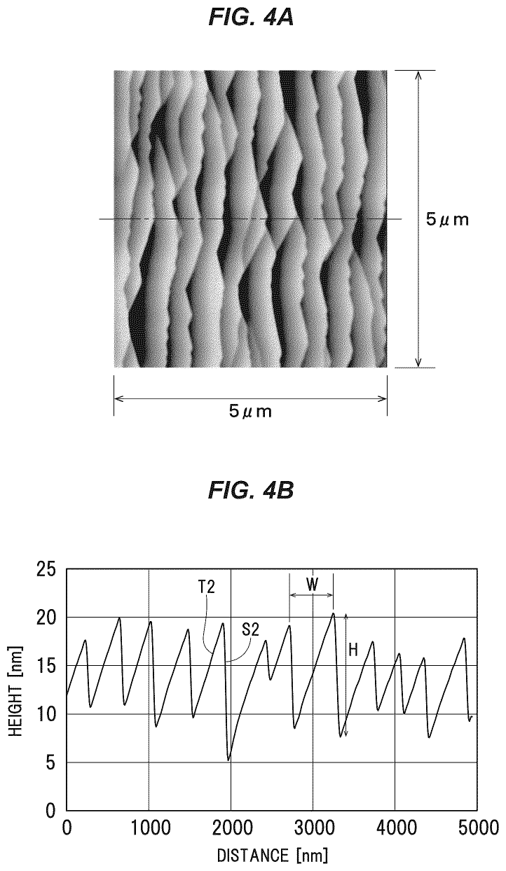

The average step height was calculated as follows: First, wafers grown up to the AlN buffer layer were prepared respectively under the same manufacturing conditions as those used for Examples 1 to 5 and Comparative Examples 1 to 3. Next, the shape of the upper surface of the AlN buffer layer of each wafer was measured by AFM. The AFM image of the upper surface of the AlN buffer layer of the wafer grown under same manufacturing conditions as Example 1 is shown in FIG. 3A, and the AFM image of the upper surface of the AlN buffer layer of the wafer grown under same manufacturing conditions as Comparative Example 1 is shown in FIG. 4A. In this Example, a 5 μm-square area at the center of the upper surface of each wafer was measured.

Next, cross-sectional profiles along both the up-and-down direction and the direction in which the terraces and steps are continuous were obtained from five arbitrary locations in each obtained AFM image. The cross-sectional profile of a position indicated by a dash-dot line in FIG. 3A is shown in FIG. 3B, and the cross-sectional profile of a position indicated by a dash-dot line in FIG. 4A is shown in FIG. 4B.

Then, the heights H of all steps S2 appeared in the five cross-sectional profiles obtained from each AFM image were measured and averaged, and the average step height was thereby calculated. Extremely small steps appear in FIG. 3B, and such extremely small steps are also each counted as one step.

Likewise, the widths W of all terraces T2 appeared in the five cross-sectional profiles obtained from each AFM image were measured and averaged, and the average terrace width was thereby calculated. In this Experimental Example, a length in the left-right direction (i.e., a direction which is one of directions orthogonal to up-and-down direction and in which the terraces and the steps are continuous) between upward vertices located on both the left and right sides of the terrace T2 in the cross-sectional profile as shown in FIGS. 3B and 4B is regarded as the width W of the terrace T2. Extremely small terraces appear in FIG. 3B, and such extremely small terraces are also each counted as one terrace.

In this regard, in FIGS. 3B and 4B, the terraces appeared on both the left and right ends are cut off midway, so the exact width of the entire terrace cannot be measured. Such only partially appeared terraces were ignored in calculating the average terrace width. The same applies to the case where steps appear on both the left and right ends and are cut off midway.

The average step heights and the average terrace widths calculated as above for Examples 1 to 5 and Comparative Examples 1 to 3 are shown in Table 2. Table 2 also shows light outputs of the wafers in Examples 1 to 5 and Comparative Examples 1 to 3, which will be described later.

TABLE 2

| | Average step | Average terrace | Light |
|---|---|---|---|
| | height [nm] | width [nm] | output [μW] |
| Example 1 | 5.60 | 311.13 | 3223.79 |
| Example 2 | 5.27 | 307.28 | 3211.94 |
| Example 3 | 6.84 | 323.25 | 3234.54 |
| Example 4 | 5.41 | 276.56 | 3159.44 |
| Example 5 | 7.09 | 349.56 | 3076.84 |
| Comparative | 7.50 | 382.92 | 2795.13 |
| Example 1 | | | |
| Comparative | 8.54 | 395.08 | 2845.35 |
| Example 2 | | | |
| Comparative | 8.95 | 421.86 | 2641.37 |
| Example 3 | | | |

As shown in Table 2, the average step height of not more than 7.1 nm and the average terrace width of not more than 350 nm are satisfied in Examples 1 to 5, while the average step height is more than 7.1 nm and the average terrace width is more than 350 nm in Comparative Examples 1 to 3.

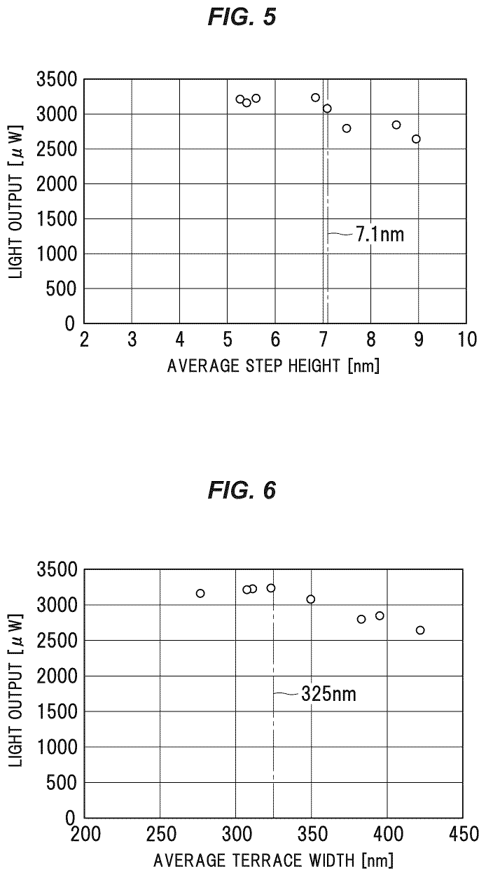

Then, in each of Examples 1 to 5 and Comparative Examples 1 to 3, a current of 20 mA was applied in the on-wafer state and light output was measured. The light output in each of Examples 1 to 5 and Comparative Examples 1 to 3 was measured by a photodetector placed on the lower side (i.e., on the substrate side) in each of Examples 1 to 5 and Comparative Examples 1 to 3. The relationship between the average step height and the light output is shown in FIG. 5, and the relationship between the average terrace width and the light output is shown in FIG. 6. In this regard, the emission wavelengths in Examples 1 to 5 and Comparative Examples 1 to 3 were not less than 260 nm and not more than 290 nm.

As understood from Table 2 and FIGS. 5 and 6, the light output in Examples 1 to 5 with the average step height of not more than 7.1 nm and the average terrace width of not more than 350 nm is higher than the light output in Comparative Examples 1 to 3 with the average step height of more than 7.1 nm and the average terrace width of more than 350 nm.

In addition, by setting the average step height to less than 7.0 nm as in Examples 1 to 4, it is possible to further increase the light output. Furthermore, there is a tendency that the higher the average step height, the larger the average terrace width is, hence, the average terrace width is preferably not more than 325 nm from the viewpoint of having the average step height of less than 7.0 nm.

### Summary of the Embodiment

Technical ideas understood from the embodiment will be described below citing the reference signs, etc., used for the embodiment. However, each reference sign, etc., described below is not intended to limit the constituent elements in the claims to the members, etc., specifically described in the embodiment.

A first embodiment of the invention includes a nitride semiconductor light-emitting element 1 comprising: a substrate 2 comprising a growth surface 21 that is a c-plane having an off angle θ; an AlN buffer layer 3 comprising AlN and being formed on the growth surface 21; an n-type semiconductor layer 4 formed on the AlN buffer layer 3; an active layer 6 being formed on the n-type semiconductor layer 4 and emitting ultraviolet light; and a p-type semiconductor layer 8 formed on the active layer 6, wherein an upper surface 31 of the AlN buffer layer 3 comprises a step-and-terrace structure comprising a plurality of terraces T2 and a plurality of steps S2 connecting between the terraces T2, wherein an average of heights H of the plurality of steps S2 is not more than 7.1 nm, and wherein an average of widths W of the plurality of terraces T2 is not more than 350 nm.

It is thereby possible to improve the light output of the nitride semiconductor light-emitting element 1.

A second embodiment of the invention includes that, in the first embodiment, the average of the heights H of the plurality of steps S2 is less than 7.0 nm.

It is thereby possible to further improve the light output of the nitride semiconductor light-emitting element 1.

A third embodiment of the invention includes that, in the first or second embodiment, the average of the widths W of the plurality of terraces T2 is not more than 325 nm.

It is thereby possible to further improve the light output of the nitride semiconductor light-emitting element 1.

A fourth embodiment of the invention includes that, in any one of the first to third embodiments of the invention, a composition gradient layer 5 being located between the n-type semiconductor layer 4 and the active layer 6 and having an Al composition ratio increasing toward the active layer 6 is further included.

It is thereby possible to further improve the light output of the nitride semiconductor light-emitting element 1.

A fifth embodiment of the invention includes that, in any one of the first to fourth embodiments, a reflective electrode 12 being formed on the p-type semiconductor layer 8 and reflecting light emitted from the active layer 6 is further included, the p-type semiconductor layer 8 comprises a p-type contact layer 82 comprising p-type GaN, and a film thickness of the p-type contact layer 82 is not more than 50 nm.

It is thereby possible to further improve the light output of the nitride semiconductor light-emitting element 1.

### Additional Note

Although embodiments of the invention have been described, the invention according to claims is not to be limited to the embodiments described above. Further, please note that not all combinations of the embodiments described above are necessary to solve the problem of the invention. In addition, the invention can be appropriately modified and implemented without departing from the gist thereof. For example, a configuration in which the configurations of the above-described embodiment are appropriately combined may be adopted.

1. A nitride semiconductor light-emitting element, comprising:
a substrate comprising a growth surface that is a c-plane having an off angle;
an AlN buffer layer comprising AlN and being formed on the growth surface;
an n-type semiconductor layer formed on the AlN buffer layer;
an active layer being formed on the n-type semiconductor layer and emitting ultraviolet light; and
a p-type semiconductor layer formed on the active layer,
wherein an upper surface of the AlN buffer layer comprises a step-and-terrace structure comprising a plurality of terraces and a plurality of steps connecting between the terraces,
wherein an average of heights of the plurality of steps is not more than 7.1 nm, and
wherein an average of widths of the plurality of terraces is not more than 350 nm.

2. The nitride semiconductor light-emitting element according to claim 1, wherein the average of the heights of the plurality of steps is less than 7.0 nm.

3. The nitride semiconductor light-emitting element according to claim 2, wherein the average of the widths of the plurality of terraces is not more than 325 nm.

4. The nitride semiconductor light-emitting element according to claim 1, further comprising:
a composition gradient layer being located between the n-type semiconductor layer and the active layer and having an Al composition ratio increasing toward the active layer.

5. The nitride semiconductor light-emitting element according to claim 1, further comprising:
a reflective electrode being formed on the p-type semiconductor layer and reflecting light emitted from the active layer,
wherein the p-type semiconductor layer comprises a p-type contact layer comprising p-type GaN, and wherein a film thickness of the p-type contact layer is not more than 50 nm.
